(19) United States
(12) Patent Application Publication
(10) Pub. No.: US 2025/0212489 A1
(43) Pub. Date: Jun. 26, 2025

(54) SEMICONDUCTOR DEVICES

(71) Applicant: SAMSUNG ELECTRONICS CO., LTD., SUWON-SI (KR)

(72) Inventors: HYOSIK MUN, Suwon-si (KR); SEYOUNG KIM, Suwon-si (KR); JAEHAN PARK, Suwon-si (KR); SUKJIN CHUNG, Suwon-si (KR); BEOM-JONG KIM, Suwon-si (KR); SUHWAN KIM, Suwon-si (KR); HYUNGSUK JUNG, Suwon-si (KR)

(21) Appl. No.: 18/814,920

(22) Filed: Aug. 26, 2024

(30) Foreign Application Priority Data
Dec. 20, 2023 (KR) 10-2023-0187425

(51) Int. Cl. H01L 29/49; H10B 12/00

(52) U.S. Cl. CPC H10D 64/665; H10B 12/315; H10B 12/482; H10B 12/488; H10B 12/50

(57) ABSTRACT

A semiconductor device may include a substrate, bottom electrodes disposed on the substrate, a supporting pattern disposed between the bottom electrodes, when viewed in a plan view, an upper electrode covering the bottom electrodes and the supporting pattern, a dielectric layer disposed between the bottom electrodes and the upper electrode and between the supporting pattern and the upper electrode and a first conductive contact connected to the upper electrode. The upper electrode comprises a metal layer, a first hydrogen diffusion barrier layer, and a first semiconductor layer, which are sequentially stacked on the dielectric layer. The first conductive contact is spaced apart from the first hydrogen diffusion barrier layer.

### CROSS-REFERENCE TO RELATED APPLICATIONS

This U.S. non-provisional patent application claims priority under 35 U.S.C. § 119 to Korean Patent Application No. 10-2023-0187425, filed on Dec. 20, 2023, in the Korean Intellectual Property Office, disclosure of which is incorporated by reference herein in its entirety.

### 1. TECHNICAL FIELD

The present disclosure relates to a semiconductor device, and in particular, to a semiconductor memory device including a hydrogen diffusion barrier layer.

### 2. DISCUSSION OF THE RELATED ART

Semiconductor devices encompass various categories, including semiconductor memory device for storing data, a semiconductor logic device for processing data, and a hybrid semiconductor device including both memory and logic elements.

With the recent trend of high speed and low power consumption of electronic devices, semiconductor devices in the electronic devices are also required to meet demands for increased operating speeds and/or reduced operating voltages, which require higher integration densities of semiconductor devices. However, as the integration density of the semiconductor device increases, the electrical characteristics of the semiconductor device may be deteriorated Accordingly, many studies are being conducted to improve the electrical characteristics of the semiconductor device.

### SUMMARY

An embodiment of the inventive concept provides a semiconductor device with improved electrical characteristics.

According to an embodiment of the inventive concept, a semiconductor device may include a substrate, bottom electrodes disposed on the substrate, a supporting pattern disposed between the bottom electrodes, when viewed in a plan view, an upper electrode covering the bottom electrodes and the supporting pattern, a dielectric layer disposed between the bottom electrodes and the upper electrode and between the supporting pattern and the upper electrode and a first conductive contact connected to the upper electrode. The upper electrode comprises a metal layer, a first hydrogen diffusion barrier layer, and a first semiconductor layer, which are sequentially stacked on the dielectric layer. The first conductive contact is spaced apart from the first hydrogen diffusion barrier layer.

According to an embodiment of the inventive concept, a semiconductor device may include a substrate, bottom electrodes on the substrate, a supporting pattern disposed between the bottom electrodes, when viewed in a plan view, an upper electrode covering the bottom electrodes and the supporting pattern and a dielectric layer provided between the bottom electrodes and the upper electrode and between the supporting pattern and the upper electrode. The upper electrode comprises a metal layer, a first semiconductor layer, a first hydrogen diffusion barrier layer, and a second semiconductor layer, which are sequentially stacked on the dielectric layer. Each of the first and second semiconductor layers comprises silicon germanium.

According to an embodiment of the inventive concept, a semiconductor device may include a substrate including a cell array region and a peripheral region, a word line disposed on the cell array region of the substrate, a first impurity region disposed in a portion of the substrate at a side of the word line, a second impurity region disposed in a portion of the substrate at an opposite side of the word line, a bit line disposed on the cell array region of the substrate crossing the word line and connected to the first impurity region, bottom electrodes disposed on the cell array region of the substrate and connected to the second impurity region, a supporting pattern disposed between the bottom electrodes, when viewed in a plan view, an upper electrode covering the bottom electrodes and the supporting pattern, a dielectric layer disposed between the bottom electrodes and the upper electrode and between the supporting pattern and the upper electrode and a first conductive contact coupled to the upper electrode. The upper electrode comprises a metal layer, a first hydrogen diffusion barrier layer, and a first semiconductor layer, which are sequentially stacked on the dielectric layer. The first conductive contact is spaced apart from the first hydrogen diffusion barrier layer and is in contact with the first semiconductor layer.

### BRIEF DESCRIPTION OF THE DRAWINGS

FIG. 1 is a plan view illustrating a semiconductor device according to an embodiment of the inventive concept.

FIG. 2A is sectional views taken along lines A-A′ and B-B′ of FIG. 1.

FIGS. 2B and 2C are sectional views illustrating modified examples of the semiconductor device of FIG. 2A and corresponding to the lines A-A′ and B-B′ of FIG. 1.

FIG. 3A is sectional views, which are taken along the lines A-A′ and B-B′ of FIG. 1 to illustrate a semiconductor device according to an embodiment of the inventive concept.

FIGS. 3B and 3C are sectional views illustrating modified examples of the semiconductor device of FIG. 3A and corresponding to the lines A-A′ and B-B′ of FIG. 1.

FIG. 4 is a sectional view illustrating the semiconductor device of FIG. 2A, taken along a line C-C′ of FIG. 1.

FIG. 5A is an enlarged sectional view illustrating a portion ‘P1’ of FIG. 4.

FIG. 5B is an enlarged sectional view illustrating a portion ‘P2’ of FIG. 4.

FIG. 6 is a sectional view illustrating the semiconductor device of FIG. 3A, taken along the line C-C′ of FIG. 1.

FIG. 7A is an enlarged sectional view illustrating a portion P3 of FIG. 6.

FIG. 7B is an enlarged sectional view illustrating a portion P4 of FIG. 6.

FIGS. 8, 9, 10, 11, 12 and 13 are sectional views sequentially illustrating a process of fabricating the semiconductor device of FIG. 4.

FIGS. 14 and 15 are sectional views illustrating a process of fabricating the semiconductor device of FIG. 6.

### DETAILED DESCRIPTION OF THE EMBODIMENTS

Example embodiments of the inventive concepts will now be described more fully with reference to the accompanying drawings, in which example embodiments are shown.

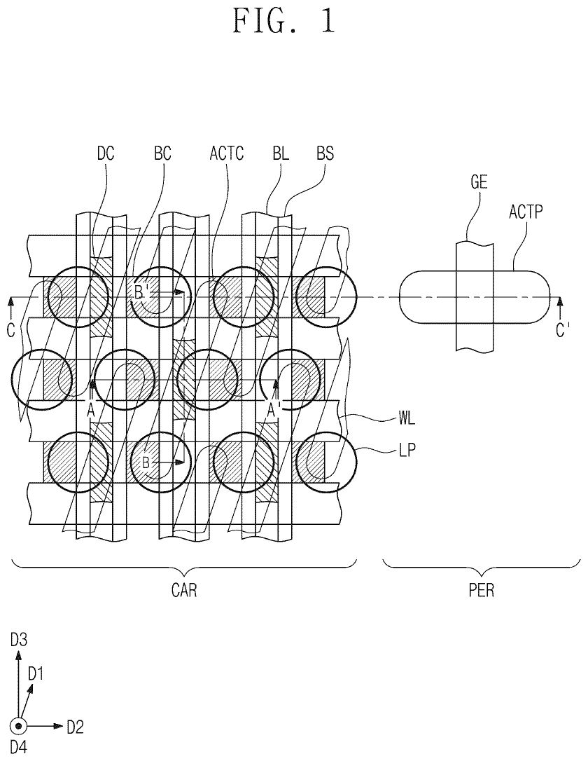

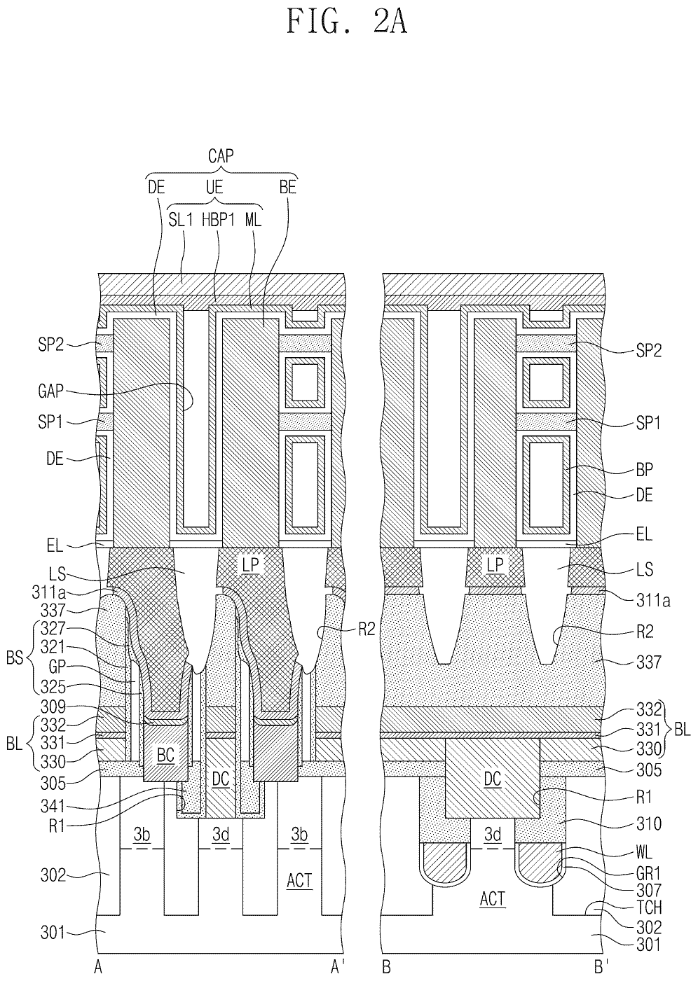

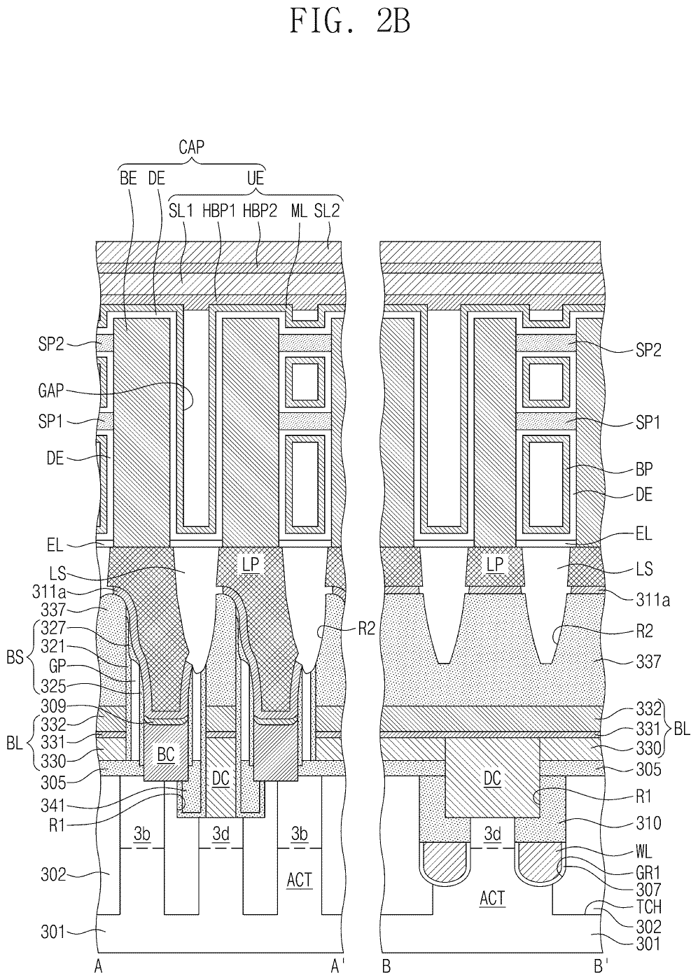

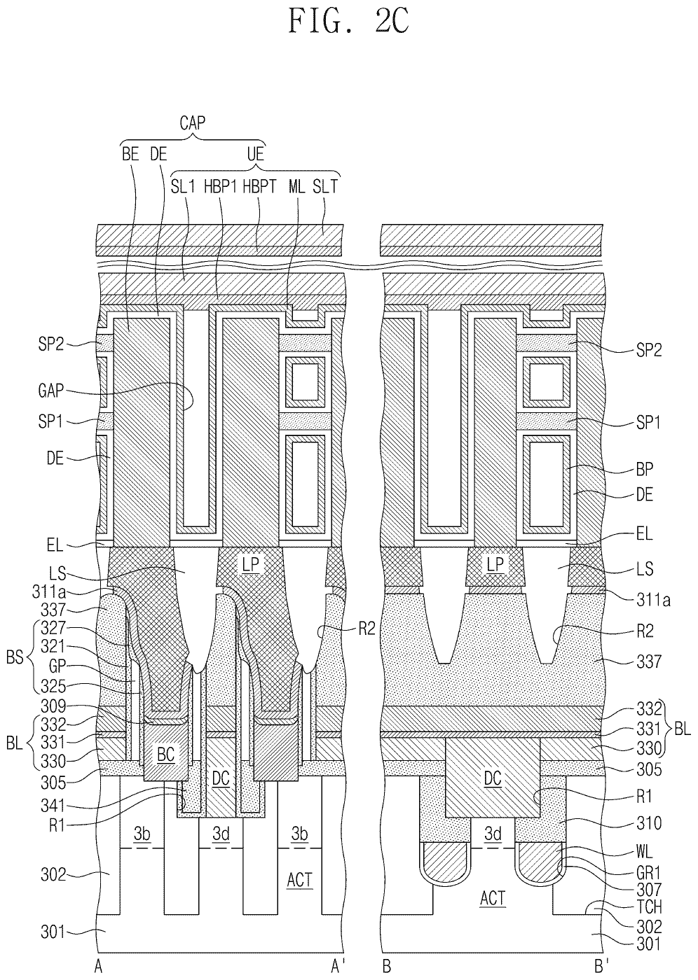

FIG. 1 is a plan view illustrating a semiconductor device according to an embodiment of the inventive concept. FIG. 2A is sectional views taken along lines A-A′ and B-B′ of FIG. 1.

Referring to FIGS. 1 and 2, a substrate 301 including a cell array region CAR and a peripheral region PER may be provided. The peripheral region PER may be disposed adjacent to the cell array region CAR. Word lines WL and bit lines BL may be disposed on the cell array region CAR, and peripheral circuits, which are used for driving the word lines and bit lines WL and BL, may be disposed on the peripheral region PER. The peripheral region PER may be referred to as a core region or a peripheral circuit region. The substrate 301 may be, for example, a silicon substrate, a germanium substrate, or a silicon-germanium substrate.

A device isolation layer 302 may be disposed in the substrate 301 to define active portions ACT including cell active portions ACTC and a peripheral active portion ACTP. The device isolation layer 302 may be disposed in a trench TCH. Each of the cell active portions ACTC may have an isolated shape. Each of the cell active portions ACTC may be a bar-shaped pattern, which is extended along a first direction D1, when viewed in a plan view. The device isolation layer 302 may include an oxide liner, a nitride liner, and an insulating gapfill layer. The cell active portions ACTC may be arranged to be parallel to each other along the first direction D1, and each cell active portion ACTC may have an end portion that is adjacent to a center of another cell active portion ACTC adjacent thereto.

The word lines WL may cross the cell active portions ACTC. The word lines WL may be disposed in groove GR1, which are formed in the device isolation layer 302 and the cell active portions ACTC. For example, the grooves GR1 may be disposed around the word lines WL. The word lines WL may be disposed parallel to a second direction D2, which is not parallel to the first direction D1. The word lines WL may be recessed, in the substrate 301.

The word lines WL may be include a conductive material. A gate insulating layer 307 may be disposed between the word lines WL and an inner surface of each of the grooves GR1.

For example, the gate insulating layer 307 may surround and be in direct contact with the word lines WL. The groove GR1 may be have a relatively larger depth in the device isolation layers 302 and a relatively smaller depth in active portions ACT. The gate insulating layer 307 may be formed of or include at least one of thermal oxide, silicon nitride, silicon oxynitride, or high-k dielectric materials. Each of the word lines WL may have an uneven bottom surface. For example, the word lines WL may have a round bottom surface.

A first impurity region 3d may be disposed in each of the cell the active portions ACTC arranged between each pair of the word lines WL, and a pair of second impurity regions 3b may be disposed in opposite edge regions of each of the cell the active portions ACTC. In an embodiment of the present inventive concept, the first and second impurity regions 3d and 3b may be doped with n-type impurities. The first impurity region 3d may correspond to a common drain region, and the second impurity regions 3b may correspond to a source region.

Each of the word lines WL and the first and second impurity regions 3d and 3b adjacent thereto may constitute a transistor. Since the word lines WL are disposed in the grooves GR1, a channel region below the word line WL may have an increased channel length within a given planar area. Thus, it may be possible to suppress the short channel effect or the like.

Top surfaces of the word lines WL may be disposed at a lower level than top surfaces of the cell the active portions ACTC. A word line capping pattern 310 may be disposed on each of the word lines WL. The word line capping patterns 310 may be line-shaped patterns, which extend along a length direction of the word lines WL, which is a horizontal direction. The word line capping patterns 310 may cover the entire top surface of the word line WL thereunder. The word line capping patterns 310 may fill the grooves GR1 on the word lines WL. The word line capping pattern 310 may be formed of or include, for example, silicon nitride.

An interlayer insulating pattern 305 may be disposed on the substrate 301. The interlayer insulating pattern 305 may be formed of or include at least one of silicon oxide, silicon nitride, or silicon oxynitride and may have a single- or multi-layered structure. The interlayer insulating pattern 305 may be island-shaped patterns, which are spaced apart from each other along a horizontal direction, when viewed in a plan view. The interlayer insulating pattern 305 may cover both end portions of two active portions ACT, which are adjacent to each other.

The substrate 301, the device isolation layer 302, and an upper portion of the word line capping pattern 310 may be partially recessed and form a first recess region R1. A portion of side surface of the first recess region R1 may be aligned with a side surface of the interlayer insulating pattern 305.

The bit lines BL may be disposed on the interlayer insulating pattern 305. The bit lines BL may at least partially cover the word line capping patterns 310 and the word lines WL. The bit lines BL may be disposed parallel to a third direction D3 that is non-parallel to the first and second directions D1 and D2. The bit lines BL may include a bit line polysilicon pattern 330, a bit line diffusion prevention pattern 331, and a bit line metal-containing pattern 332 sequentially stacked on top of each other. The bit line polysilicon pattern 330 may be formed of or include doped polysilicon. The bit line diffusion prevention pattern 331 may be formed of or include at least one of metal nitride materials (e.g., titanium nitride). The bit line metal-containing pattern 332 may be formed of or include at least one of metallic materials (e.g., tungsten, titanium, and tantalum) or conductive metal nitride materials (e.g., titanium nitride, tantalum nitride, and tungsten nitride). A bit line capping pattern 337 may be disposed on each of the bit lines BL. The bit line capping patterns 337 may be formed of or include an insulating material (e.g., silicon nitride).

Bit line contacts DC may be disposed in the first recess region R1. and the bit line contacts DC may vertically cross the bit lines BL. The bit line contacts DC may be formed of or include doped or undoped polysilicon. A side surface of the bit line contact DC may be in contact with a side surface of the interlayer insulating pattern 305. Referring to FIG. 1, a side surface of the bit line contact DC in contact with the interlayer insulating pattern 305 may be concave shaped. The bit line contact DC may electrically connect the first impurity region 3d to the bit line BL.

A lower gapfill insulating pattern 341 may be formed in a portion of the first recess region R1 where it is not filled with the bit line contact DC. For example, the lower gapfill insulating pattern 341 may be disposed adjacent to side surfaces of the bit line contact DC. The lower gapfill insulating pattern 341 may be formed of or include at least one of silicon oxide, silicon nitride, or silicon oxynitride and may have a single- or multi-layered structure.

Storage node contacts BC may be disposed between a pair of the bit lines BL, which are adjacent to each other. The storage node contacts BC may be spaced apart from each other. The storage node contacts BC may include doped polysilicon. The storage node contacts BC may have concave top surfaces. An insulating pattern may be provided between the bit lines BL and between the storage node contacts BC.

A bit line spacer BS may be interposed between the bit line BL and the storage node contact BC. The bit line spacer BS may include a first sub-spacer 321 and a second sub-spacer 325, which are spaced apart from each other by a gap region GP. The gap region GP may be referred to as an air gap region. The first sub-spacer 321 may cover a side surface of the bit line BL and a side surface of the bit line capping pattern 337. The second sub-spacer 325 may be disposed adjacent to the storage node contact BC. For example, the second sub-spacer 325 may cover a side surface of the storage node contacts BC. The first and second sub-spacers 321 and 325 may include the same material. For example, the first and second sub-spacers 321 and 325 may be formed of or include silicon nitride.

A height of an upper end of the second sub-spacer 325 may be disposed at a lower level than a height of an upper end of the first sub-spacer 321. The first sub-spacer 321 may cover a side surface of the bit line contact DC and side and bottom surfaces of the first recess region R1. For example, the first sub-spacer 321 may be interposed between the bit line contact DC and the lower gapfill insulating pattern 341, between the word line capping pattern 310 and the lower gapfill insulating pattern 341, between the substrate 301 and the lower gapfill insulating pattern 341, and between the device isolation layer 302 and the lower gapfill insulating pattern 341.

A storage node ohmic layer 309 may be disposed on the storage node contact BC. The storage node ohmic layer 309 may include metal silicide. The storage node ohmic layer 309 may be formed of or include, for example, cobalt silicide. A diffusion prevention pattern 311a may conformally cover the storage node ohmic layer 309, the first and second sub-spacers 321 and 325, and the bit line capping pattern 337. The diffusion prevention pattern 311a may include at least one of metal nitride materials (e.g., titanium nitride and tantalum nitride). A landing pad LP may be disposed on the diffusion prevention pattern 311a. The landing pad LP may be formed of or include at least one of metal-containing materials (e.g., tungsten). An upper portion of the landing pad LP may cover at least a portion of a top surface of the bit line capping pattern 337 and may have a larger width than the storage node contact BC. A center of the landing pad LP may be shifted from a center of the storage node contact BC along the second direction D2. A portion of the bit line BL may be vertically overlapped with the landing pad LP. An upper side surface of the bit line capping pattern 337 may be overlapped with the landing pad LP and may be at least partially covered with a third sub-spacer 327. Another upper side surface of the bit line capping pattern 337 may define a second recess region R2.

A sum of widths of the first and third sub-spacers 321 and 327, which are measured at an upper level of the bit line spacer BS, may be smaller than a sum of widths of the first sub-spacer 321, the gap region GP, and the second sub-spacer 325, which are measured at a lower level of the bit line spacer BS. The difference in the sum of widths may increase a process margin in a subsequent process of forming a landing pad LP. Thus, it may be possible to prevent a disconnection or open issue between the landing pad LP and the storage node contact BC.

A landing pad separation pattern LS may be disposed on the second recess region R2. An upper end of the gap region GP may be defined by the landing pad separation pattern LS. For example, the landing pad separation pattern LS may at least partially cover the upper end of the gap region GP. The landing pad separation pattern LS may include at least one of a silicon nitride layer, a silicon oxide layer, a silicon oxynitride layer, a silicon carbon nitride layer, or a porous layer. A top surface of the landing pad separation pattern LS may be coplanar with top surfaces of the landing pads LP. Between bottom electrodes BE, the landing pad separation pattern LS may be covered with an etch stop layer EL. The etch stop layer EL may be formed of or include at least one of insulating materials (e.g., silicon nitride, silicon oxide, and silicon oxynitride).

The bottom electrodes BE may be disposed on the landing pads LP, respectively. The bottom electrode BE may be formed of or include at least one of doped polysilicon, metal nitride materials (e.g., titanium nitride), or metallic materials (e.g., tungsten, aluminum, and copper). The bottom electrode BE may have a circular pillar shape, a hollow cylinder shape, or a cup shape.

Upper side surfaces of the bottom electrodes BE, which are disposed adjacent to each other may be connected to each other by supporting patterns SP. The supporting pattern SP may include a first supporting pattern SP1 and a second supporting pattern SP2. The second supporting pattern SP2 may be located at a level higher than the first supporting pattern SP1 and may be spaced apart from each other along a vertical direction. The second supporting pattern SP2 may be in contact with upper side surfaces of the bottom electrodes BE. The first supporting pattern SP1 may be in contact with intermediate side surfaces of the bottom electrodes BE. The first and second supporting patterns SP1 and SP2 may be formed of or include an insulating material (e.g., silicon nitride, silicon oxide, silicon oxynitride, or silicon carbon nitride). The first and second supporting patterns SP1 and SP2 may prevent the bottom electrodes BE from falling or collapsing during a process of fabricating a semiconductor device. In the present specification, the supporting patterns are illustrated to have a double-layered structure including the first and second supporting patterns SP1 and SP2, but the inventive concept is not limited to this example. For example, the semiconductor device may include one supporting pattern or include first to third supporting patterns located at different levels. However, for the sake of brevity, the description that follows will refer to a semiconductor device including the first and second supporting patterns SP1 and SP2.

A dielectric layer DE may be provided on the first supporting pattern SP1, the second supporting pattern SP2, and the bottom electrodes BE. The dielectric layer DE may conformally cover the first supporting pattern SP1, the second supporting pattern SP2, and the bottom electrodes BE. For example, the dielectric layer DE may be interposed between the bottom electrodes BE and an upper electrode UE and between the second supporting pattern SP2 and the upper electrode UE. The dielectric layer DE may have the same crystal structure as that of the bottom electrodes BE. For example, the dielectric layer DE may have a tetragonal structure. In an embodiment, the dielectric layer DE may be formed of or include at least one of metal oxide materials (e.g., HfO₂, ZrO₂, Al2O₃, La₂O₃, Ta₂O₃, and TiO₂) or perovskite dielectric materials (e.g., SrTiO₃ (STO), (Ba,Sr)TiO₃ (BST), BaTiO₃, PZT, and PLZT) and may have a single- or multi-layered structure.

The upper electrode UE may be provided on the dielectric layer DE and cover the first supporting pattern SP1, the second supporting pattern SP2, and the bottom electrodes BE. The bottom electrodes BE, the dielectric layer DE, and the upper electrode UE may constitute a capacitor CAP. As an example, the capacitor CAP may serve as a data storing element in a semiconductor device according to an embodiment of the inventive concept.

The upper electrode UE may include a metal layer ML, a first hydrogen diffusion barrier layer HBP1, and a first semiconductor layer SL1, which are sequentially stacked on the dielectric layer DE. The metal layer ML may conformally cover the dielectric layer DE. The metal layer ML may be formed of or include titanium nitride (TiN).

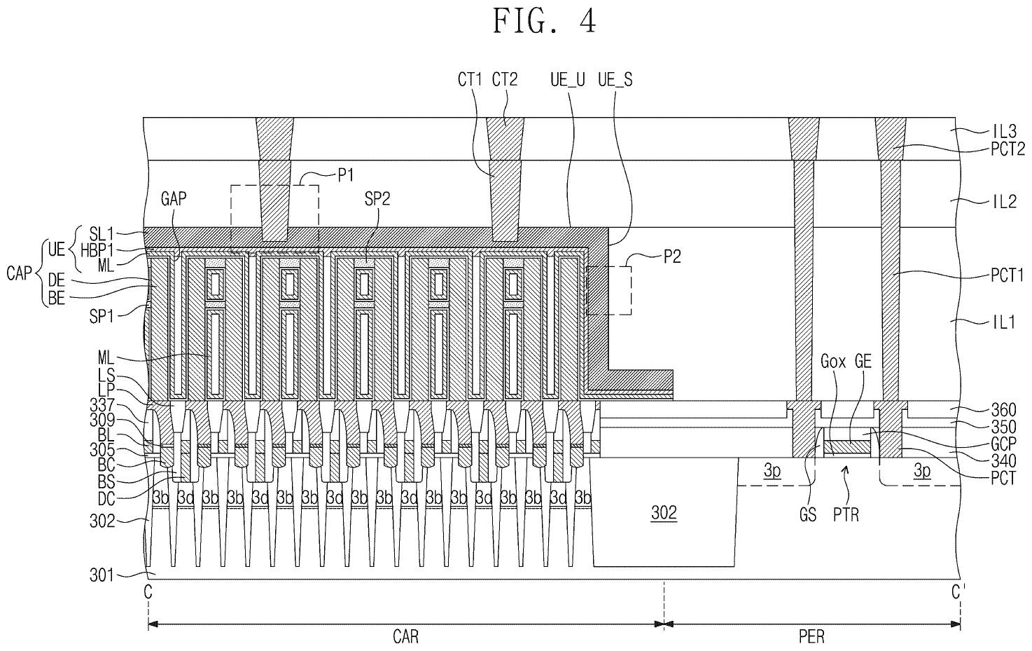

The first hydrogen diffusion barrier layer HBP1 may be disposed on the metal layer ML. The first hydrogen diffusion barrier layer HBP1 may be in contact with a portion of a top surface of the metal layer. For example, a portion of a bottom surface of the first hydrogen diffusion barrier layer HBP1 may be in contact with a top surface of the metal layer ML. However, a portion of the first hydrogen diffusion barrier layer HBP1 might not be in contact with the metal layer ML. For example, a portion of the bottom surface of the first hydrogen diffusion barrier layer HBP1 may be spaced apart from the metal layer ML and expose a portion of the top surface of the metal layer ML. Here, a gap portion GAP may be formed between the metal layer ML and the first hydrogen diffusion barrier layer HBP1. The gap portion GAP may be a portion that is not filled with a conductive material or a dielectric material. In an embodiment, the first hydrogen diffusion barrier layer HBP1 may be formed of or include at least one of titanium (Ti), tungsten (W), titanium nitride (TiN), tungsten nitride (WN), titanium silicon nitride (TSN), or tungsten silicon nitride (WSN). Furthermore, as will be described with reference to FIGS. 4 to 7B, the first hydrogen diffusion barrier layer HBP1 may prevent hydrogen atoms from being diffused from the conductive contacts and the first interlayer insulating layer into the metal layer ML and the dielectric layer DE.

The first semiconductor layer SL1 may be disposed on the first hydrogen diffusion barrier layer HBP1. The first semiconductor layer SL1 may conformally cover the first hydrogen diffusion barrier layer HBP1. In an embodiment of the inventive concepts, the first semiconductor layer SL1 may be formed of or include silicon germanium (SiGe). The conductive contacts may be connected to the first semiconductor layer SL1.

A thickness of the first hydrogen diffusion barrier layer HBP1 may be smaller than a thickness of the first semiconductor layer SL1. In an embodiment of the inventive concepts, the first hydrogen diffusion barrier layer HBP1 may have a thickness ranging from about 100 Å to 300 Å, the first semiconductor layer SL1 may have a thickness ranging from about 1000 Å to 3000 Å, but the inventive concept is not limited to this example. The thickness of the first hydrogen diffusion barrier layer HBP1 may be variously changed, as long as the first hydrogen diffusion barrier layer HBP1 can effectively prevent the hydrogen atom from being diffused into the metal layer ML and the dielectric layer DE.

FIGS. 2B and 2C are sectional views illustrating modified examples of the semiconductor device of FIG. 2A and corresponding to the lines A-A′ and B-B′ of FIG. 1. To the extent that an element has not been described in detail, it may be assumed that the element is at least similar to corresponding elements that have been described in previous figures.

Referring to FIG. 2B, the upper electrode UE may further include a second hydrogen diffusion barrier layer HBP2 disposed on the first semiconductor layer SL1 and a second semiconductor layer SL2 disposed on the second hydrogen diffusion barrier layer HBP2, in addition to the metal layer ML, the first hydrogen diffusion barrier layer HBP1, and the first semiconductor layer SL1.

The second hydrogen diffusion barrier layer HBP2 may conformally cover the first semiconductor layer SL1. The second hydrogen diffusion barrier layer HBP2 may include the same or similar material as the first hydrogen diffusion barrier layer HBP1. For example, the second hydrogen diffusion barrier layer HBP2 may be formed of or include at least one of titanium (Ti), tungsten (W), titanium nitride (TiN), tungsten nitride (WN), titanium silicon nitride (TSN), or tungsten silicon nitride (WSN). The second hydrogen diffusion barrier layer HBP2, along with the first hydrogen diffusion barrier layer HBP1, may prevent hydrogen atoms from being diffused from the conductive contacts and the first interlayer insulating layer into the metal layer ML and the dielectric layer DE.

The second semiconductor layer SL2 may be disposed on the second hydrogen diffusion barrier layer HBP2 and may conformally cover the second hydrogen diffusion barrier layer HBP2. Conductive contacts may be connected to the second semiconductor layer SL2. For example, a first conductive contact (e.g., CT1 of FIG. 4) may be connected to the second semiconductor layer SL2 and may be spaced apart from the second hydrogen diffusion barrier layer HBP2. The second semiconductor layer SL2 may include the same or similar material as the first semiconductor layer SL1. In an embodiment of the inventive concepts, the second semiconductor layer SL2 may be formed of or include silicon germanium (SiGe). For example, each of the first and second semiconductor layers SL1 and SL2 may be formed of or include silicon germanium.

Referring to FIG. 2C, the upper electrode UE may further include a plurality of hydrogen diffusion barrier layers and a plurality of semiconductor layers, which are stacked on the first semiconductor layer SL1, in addition to the metal layer ML, the first hydrogen diffusion barrier layer HBP1, and the first semiconductor layer SL1.

A plurality of hydrogen diffusion barrier layers and a plurality of semiconductor layers may be alternatively stacked. For example, a second hydrogen diffusion barrier layer HBP2 may be stacked on the first semiconductor layer SL1, and a second semiconductor layer SL2 may be stacked on the second hydrogen diffusion barrier layer HBP2. Furthermore, remaining hydrogen diffusion barrier layers and remaining semiconductor layers may be alternatively stacked and form the upper electrode UE.

The uppermost layer of the upper electrode UE may be a semiconductor layer SLT. For example, a semiconductor layer SLT, which is the uppermost one of the semiconductor layers, may be placed at a level higher than a hydrogen diffusion barrier layer HBPT, which is the uppermost one of the hydrogen diffusion barrier layers. For example, one of the semiconductor layers SLT may be located at the uppermost level of the upper electrode UE. The uppermost semiconductor layer SLT may be stacked on the uppermost hydrogen diffusion barrier layer HBPT. Conductive contacts may be connected to the uppermost semiconductor layer SLT. For example, the first conductive contact CT1 of FIG. 4 may be connected to the uppermost semiconductor layer SLT and may be spaced apart from the uppermost hydrogen diffusion barrier layer HBPT.

Each of the hydrogen diffusion barrier layers may include the same or similar material as the first hydrogen diffusion barrier layer HBP1. For example, each of the hydrogen diffusion barrier layers may be formed of or include at least one of titanium (Ti), tungsten (W), titanium nitride (TiN), tungsten nitride (WN), titanium silicon nitride (TSN), or tungsten silicon nitride (WSN). The hydrogen diffusion barrier layers, along with the first hydrogen diffusion barrier layer HBP1, may prevent hydrogen atoms from being diffused from the conductive contacts and the first interlayer insulating layer into the metal layer ML and the dielectric layer DE.

Each of the semiconductor layers may include the same or similar material as the first semiconductor layer SL1. In an embodiment of the inventive concepts, each of the semiconductor layers may be formed of or include silicon germanium.

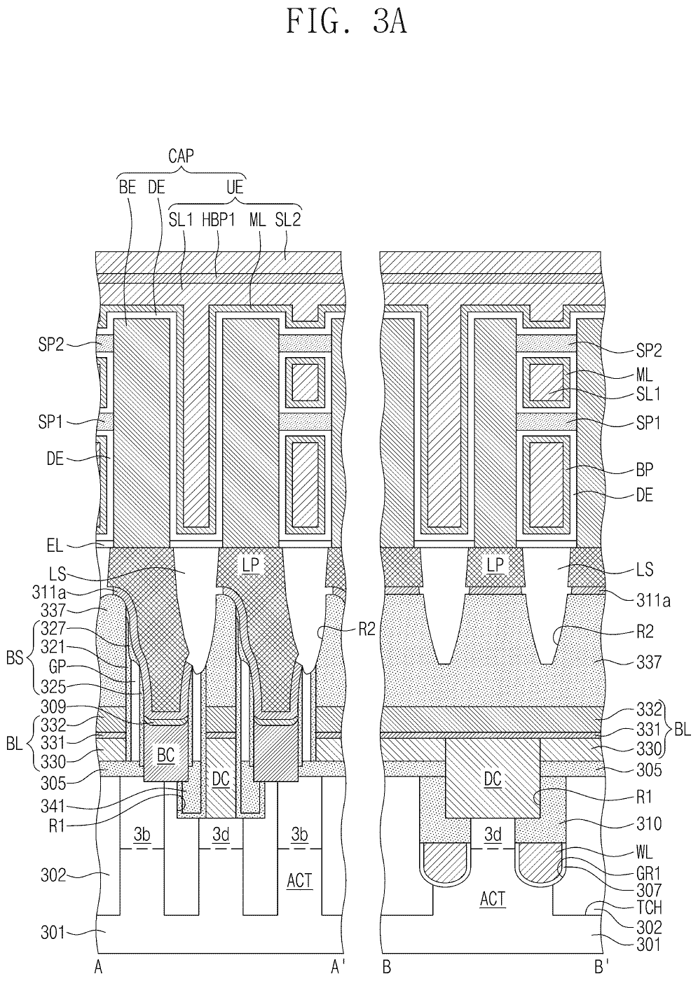

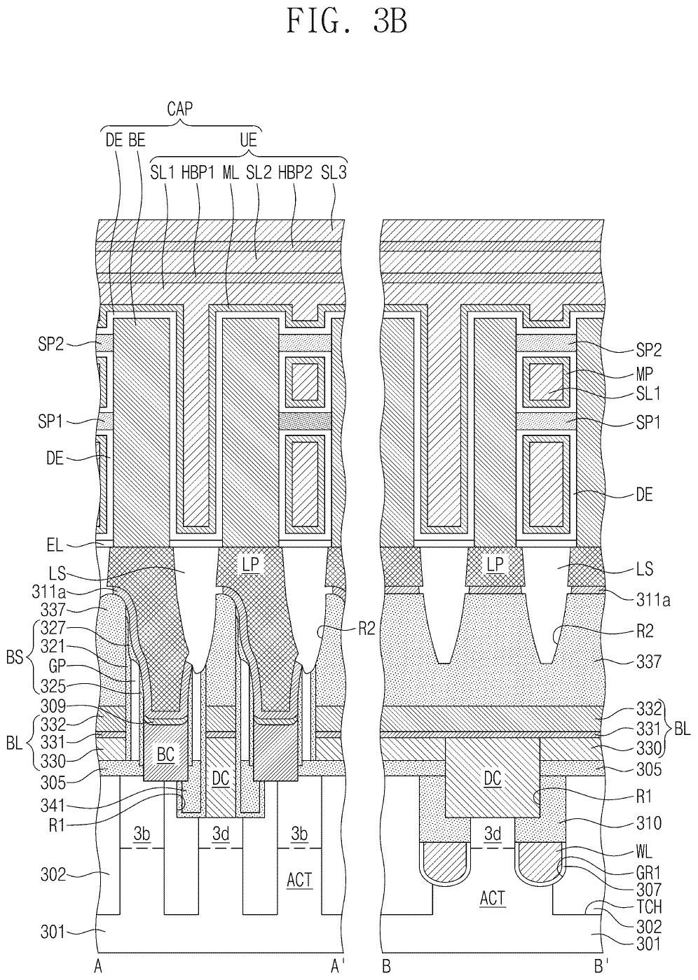

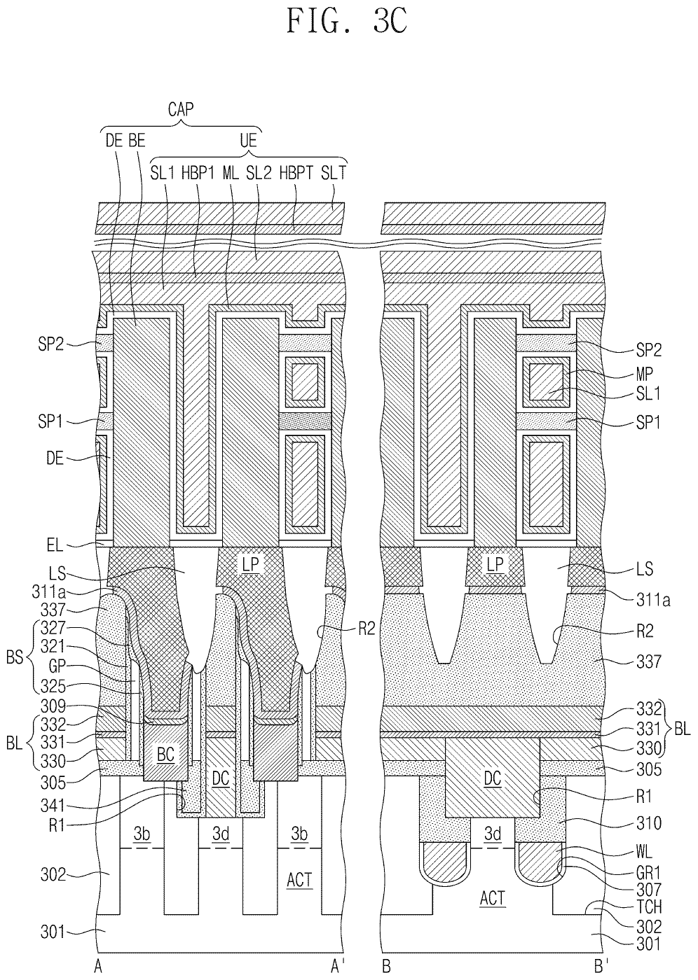

FIG. 3A is sectional views, which are taken along the lines A-A′ and B-B′ of FIG. 1 to illustrate a semiconductor device according to an embodiment of the inventive concept. To the extent that an element has not been described in detail, it may be assumed that the element is at least similar to corresponding elements that have been described in previous figures.

Referring to FIG. 3A, the upper electrode UE may include the metal layer ML, the first semiconductor layer SL1, the first hydrogen diffusion barrier layer HBP1, and the second semiconductor layer SL2, which are sequentially stacked on the dielectric layer DE. For example, the second semiconductor layer SL2 may be stacked on the first hydrogen diffusion barrier layer HBP1 which is stacked on the first semiconductor layer SL1. The upper electrode UE may fill a space between the bottom electrodes BE, a space between the first supporting pattern SP1 and the second supporting pattern SP2, and a space between the first supporting pattern SP1 and the etch stop layer EL. For example, the metal layer ML may conformally cover the dielectric layer DE, and the first semiconductor layer SL1 may cover at least the portion of the top surface of the metal layer ML. The first semiconductor layer SL1 may fill an empty space, which is placed between the bottom electrodes BE, between the first and second supporting patterns SP1 and SP2, and between the first supporting pattern SP1 and the etch stop layer EL and might not be filled with the metal layer ML. In an embodiment of the inventive concepts, the first semiconductor layer SL1 may be formed of or include silicon germanium (SiGe).

The first hydrogen diffusion barrier layer HBP1 may conformally cover the first semiconductor layer SL1. In an embodiment of the inventive concepts, the first hydrogen diffusion barrier layer HBP1 may be formed of or include at least one of titanium (Ti), tungsten (W), titanium nitride (TiN), tungsten nitride (WN), titanium silicon nitride (TSN), or tungsten silicon nitride (WSN).

The second semiconductor layer SL2 may conformally cover the first hydrogen diffusion barrier layer HBP1. The second semiconductor layer SL2 may include the same or similar material as the first semiconductor layer SL1 and may be formed of or include, for example, silicon germanium (SiGe). The conductive contacts may be connected to the second semiconductor layer SL2.

FIGS. 3B and 3C are sectional views illustrating modified examples of the semiconductor device of FIG. 3A and corresponding to the lines A-A′ and B-B′ of FIG. 1. To the extent that an element has not been described in detail, it may be assumed that the element is at least similar to corresponding elements that have been described in previous figures.

Referring to FIG. 3B, the upper electrode UE may further include a second hydrogen diffusion barrier layer HBP2 disposed on the second semiconductor layer SL2 and a third semiconductor layer SL3 disposed on the second hydrogen diffusion barrier layer HBP2, in addition to the metal layer ML, the first semiconductor layer SL1, the first hydrogen diffusion barrier layer HBP1, and the second semiconductor layer SL2.

The second hydrogen diffusion barrier layer HBP2 may conformally cover the second semiconductor layer SL2. The second hydrogen diffusion barrier layer HBP2 may include the same or similar material as the first hydrogen diffusion barrier layer HBP1. For example, the second hydrogen diffusion barrier layer HBP2 may be formed of or include at least one of titanium (Ti), tungsten (W), titanium nitride (TiN), tungsten nitride (WN), titanium silicon nitride (TSN), or tungsten silicon nitride (WSN). The second hydrogen diffusion barrier layer HBP2, along with the first hydrogen diffusion barrier layer HBP1, may prevent hydrogen atoms from being diffused from the conductive contacts and the first interlayer insulating layer into the metal layer ML and the dielectric layer DE.

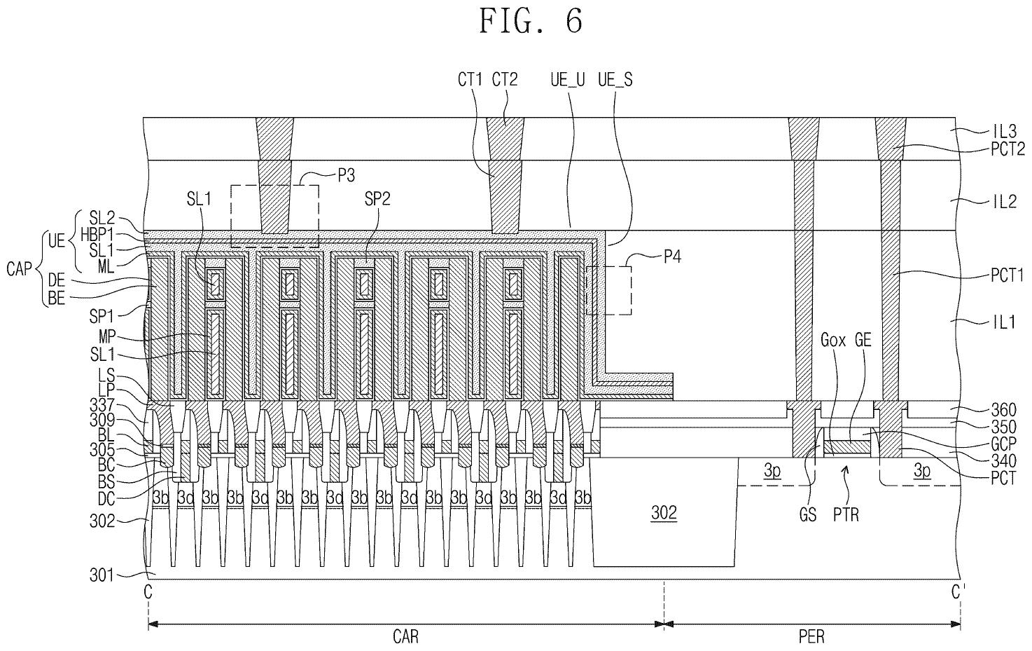

The third semiconductor layer SL3 may be disposed on the second hydrogen diffusion barrier layer HBP2 and conformally cover the second hydrogen diffusion barrier layer HBP2. Conductive contacts may be connected to the third semiconductor layer SL3. For example, a first conductive contact (e.g., CT1 of FIG. 6) may be connected to the third semiconductor layer SL3 and may be spaced apart from the second hydrogen diffusion barrier layer HBP2. The third semiconductor layer SL3 may include the same or similar material as the first and second semiconductor layers SL1 and SL2. As an example, the third semiconductor layer SL3 may be formed of or include silicon germanium (SiGe). For example, each of the first to third semiconductor layers SL1, SL2, and SL3 may be formed of or include silicon germanium.

Referring to FIG. 3C, the upper electrode UE may further include a plurality of hydrogen diffusion barrier layers and a plurality of semiconductor layers, which are stacked on the first semiconductor layer SL1, in addition to the metal layer ML, the first hydrogen diffusion barrier layer HBP1, and the first semiconductor layer SL1.

A plurality of hydrogen diffusion barrier layers and a plurality of semiconductor layers may be alternatively stacked. For example, a second hydrogen diffusion barrier layer HBP2 may be stacked on the second semiconductor layer SL2, and a third semiconductor layer SL3 may be stacked on the second hydrogen diffusion barrier layer HBP2. Furthermore, remaining hydrogen diffusion barrier layers and remaining semiconductor layers may be alternatively stacked and form the upper electrode UE.

The uppermost layer of the upper electrode UE may be a semiconductor layer. For example, the semiconductor layer SLT, which is the uppermost one of the semiconductor layers, may be placed at a level higher than the hydrogen diffusion barrier layer HBPT, which is the uppermost one of the hydrogen diffusion barrier layers. For example, one of the semiconductor layers SLT may be located at the top level of the upper electrode UE. The uppermost semiconductor layer SLT may be stacked on the uppermost hydrogen diffusion barrier layer HBPT. Conductive contacts may be connected to the uppermost semiconductor layer SLT. For example, the first conductive contact CT1 of FIG. 6 may be connected to the uppermost semiconductor layer SLT and may be spaced apart from the uppermost hydrogen diffusion barrier layer HBPT.

Each of the hydrogen diffusion barrier layers may include the same or similar material as the first hydrogen diffusion barrier layer HBP1. For example, each of the hydrogen diffusion barrier layers may be formed of or include at least one of titanium (Ti), tungsten (W), titanium nitride (TiN), tungsten nitride (WN), titanium silicon nitride (TSN), or tungsten silicon nitride (WSN). The hydrogen diffusion barrier layers, along with the first hydrogen diffusion barrier layer HBP1, may prevent hydrogen atoms from being diffused from the conductive contacts and the first interlayer insulating layer into the metal layer ML and the dielectric layer DE.

Each of the semiconductor layers may include the same or similar material as the first semiconductor layer SL1. As an example, each of the semiconductor layers may be formed of or include silicon germanium.

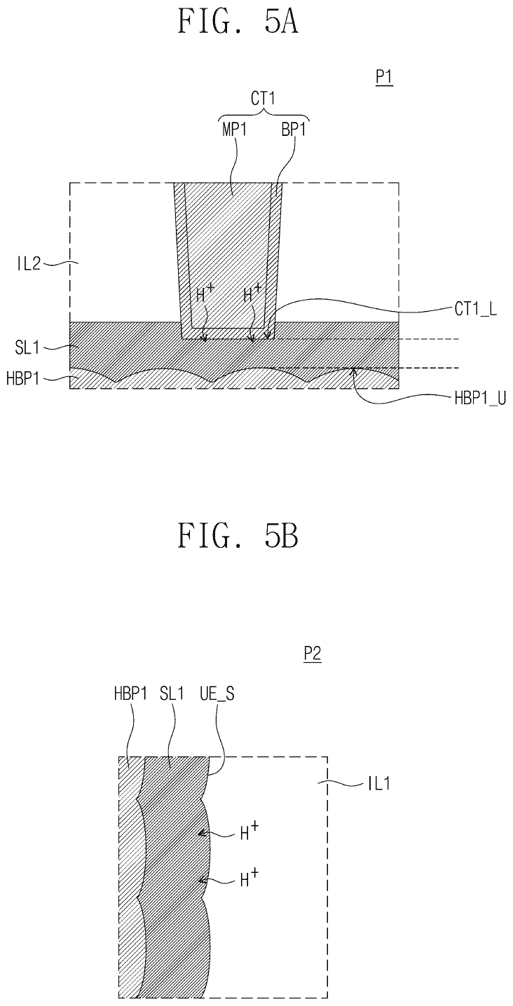

FIG. 4 is a sectional view illustrating the semiconductor device of FIG. 2A, taken along a line C-C′ of FIG. 1. FIG. 5A is an enlarged sectional view illustrating a portion ‘P1’ of FIG. 4. FIG. 5B is an enlarged sectional view illustrating a portion ‘P2’ of FIG. 4. To the extent that an element has not been described in detail, it may be assumed that the element is at least similar to corresponding elements that have been described in previous figures.

Referring to FIGS. 1 and 4, a peripheral transistor PTR may be disposed on the peripheral region PER. The peripheral transistor PTR may include a peripheral gate insulating layer Gox, a peripheral gate electrode GE, a peripheral capping pattern GCP, and a peripheral spacer GS covering side surfaces thereof. The peripheral transistor PTR may further include peripheral source/drain regions 3p, which are formed in the substrate 301 and adjacent to both sides of the peripheral gate insulating layer Gox. The peripheral region PER may be at least partially covered with a first lower insulating layer 340. In an embodiment, the first lower insulating layer 340 may be formed of or include silicon oxide. A top surface of the first lower insulating layer 340 may be coplanar with a top surface of the peripheral capping pattern GCP. A second lower insulating layer 350 may be disposed on the first lower insulating layer 340. The second lower insulating layer 350 and the peripheral capping pattern GCP may include the same material as the bit line capping pattern 337. For example, the second lower insulating layer 350 and the peripheral capping pattern GCP may be formed of or include silicon nitride. A sum of a thickness of the second lower insulating layer 350 and a thickness of the peripheral capping pattern GCP may be substantially equal to a thickness of the bit line capping pattern 337.

A first peripheral contact plug PCT may penetrate the first and second lower insulating layers 340 and 350 and may be in contact with the peripheral source/drain region 3p. The first peripheral contact plug PCT may include a protruding portion extends to a level higher than the second lower insulating layer 350. A third lower insulating layer 360 may be disposed on the second lower insulating layer 350. The third lower insulating layer 360 may include the same material as the landing pad separation pattern LS. A portion of the third lower insulating layer 360 may extend into the second lower insulating layer 350. For example, a bottom surface of the third lower insulating layer 360 may be disposed at lower level than a top end of the second lower insulating layer 350. The landing pad LP, the landing pad separation pattern LS, the third lower insulating layer 360, and the first peripheral contact plug PCT may have top surfaces that are substantially coplanar with each other.

A first interlayer insulating layer IL1 may be disposed on the peripheral region PER and cover the third lower insulating layer 360. The first interlayer insulating layer IL1 may be formed of a hydrogen-containing insulating material. In an embodiment of the inventive concepts, the first interlayer insulating layer IL1 may be formed of or include at least one of silicon oxide, silicon nitride, silicon oxynitride, or porous insulating materials (e.g., SiOCH) and may have a single- or multi-layered structure. The first interlayer insulating layer IL1 may at least partially cover a side surface UE_S of the upper electrode UE. A top surface of the first interlayer insulating layer IL1 may be coplanar with a top surface UE_U of the upper electrode UE.

A second interlayer insulating layer IL2 may be disposed on the upper electrode UE and the first interlayer insulating layer IL1. The second interlayer insulating layer IL2 may be formed of a hydrogen-containing insulating material. In an embodiment of the inventive concepts, the second interlayer insulating layer IL2 may be formed of or include at least one of silicon oxide, silicon nitride, silicon oxynitride, or porous insulating materials (e.g., SiOCH) and may have a single- or multi-layered structure.

A third interlayer insulating layer IL3 may be disposed on the second interlayer insulating layer IL2. The third interlayer insulating layer IL3 may be formed of a hydrogen-containing insulating material. In an embodiment of the inventive concepts, the third interlayer insulating layer IL3 may be formed of or include at least one of silicon oxide, silicon nitride, silicon oxynitride, or porous insulating materials (e.g., SiOCH) and may have a single- or multi-layered structure. Additional interlayer insulating layers or an additional passivation layer may be formed on the third interlayer insulating layer IL3. The additional interlayer insulating layers and the additional passivation layer may be formed of or include a hydrogen-containing insulating material.

In the cell array region CAR, a first conductive contact CT1 may penetrate the second interlayer insulating layer IL2 and may be in contact with the upper electrode UE. A second conductive contact CT2 may penetrate the third interlayer insulating layer IL3 and may be in contact with the first conductive contact CT1. Each of the first and second conductive contacts CT1 and CT2 may be formed of or include at least one of titanium nitride, tantalum nitride, tungsten nitride, tungsten, aluminum, or copper.

In the peripheral region PER, a first peripheral conductive contact PCT1 may penetrate the first and second interlayer insulating layers IL1 and IL2 and may be in contact with each of the first peripheral contact plugs PCT. A second peripheral conductive contact PCT2 may penetrate the third interlayer insulating layer IL3 and may be in contact with the first peripheral conductive contact PCT1. Each of the first and second peripheral conductive contacts PCT1 and PCT2 may be formed of or include at least one of titanium nitride, tantalum nitride, tungsten nitride, tungsten, aluminum, or copper.

To reduce a failure caused by silicon dangling bonds in the substrate 301, a thermal treatment process may be performed after the formation of the passivation layer. As a result of the thermal treatment process, hydrogen atoms in the passivation layer may be diffused into the substrate 301 through a conductive pattern and may be coupled with silicon atoms in the substrate 301. Thus, it may be possible to suppress the failure by the silicon dangling bonds. The hydrogen atoms in the passivation layer may diffuse into the first and second conductive contacts CT1 and CT2 through conductive lines on the first and second conductive contacts CT1 and CT2. Moreover, the hydrogen atoms in the passivation layer may diffuse into the first semiconductor layer SL1 via the first and second conductive contacts CT1 and CT2. In the case where the hydrogen atoms, which are diffused into the first semiconductor layer SL1, are diffused to the dielectric layer DE through the upper electrode UE, the mechanical/electrical characteristics of the semiconductor device may be deteriorated. However, according to an embodiment of the inventive concept, the first hydrogen diffusion barrier layer HBP1 may be provided in the upper electrode UE to be in contact with and enclose the metal layer ML, and thus, hydrogen atoms may be prevented from being diffused into the dielectric layer DE. Furthermore, although the first hydrogen diffusion barrier layer HBP1 is disposed in the upper electrode UE, by reducing a thickness of the first semiconductor layer SL1, it may be possible to reduce a total thickness of the upper electrode UE. Thus, it may be possible to reduce a lateral thickness of the upper electrode UE enclosing the bottom electrodes BE and to dispose additional bottom electrodes on the cell array region CAR. Accordingly, an integration density of the semiconductor device may be increased.

Referring to FIGS. 4 and 5A, the first hydrogen diffusion barrier layer HBP1, the first semiconductor layer SL1, and the second interlayer insulating layer IL2 may be sequentially disposed. For example, the second interlayer insulating layer IL2 may be disposed on the semiconductor layer SL1 which is disposed on the first hydrogen diffusion barrier layer HBP1. The first conductive contact CT1 may be formed on the first semiconductor layer SLI and penetrate the second interlayer insulating layer IL2 and may be connected to the first semiconductor layer SL1. The first conductive contact CT1 may include a first barrier pattern BP1 and a first metal pattern MP1. The first barrier pattern BP1 may be in contact with the second interlayer insulating layer IL2 and the first semiconductor layer SL1, and the first metal pattern MP1 may be formed in the first barrier pattern BP1. For example, the second interlayer insulating layer IL2 may at least partially surround the first barrier pattern BP1. The first barrier pattern BP1 may be formed of or include at least one of metal nitride materials (e.g., titanium nitride, tantalum nitride, and tungsten nitride), and the first metal pattern MP1 may be formed of or include at least one of metallic materials (e.g., tungsten, aluminum, and copper).

As described above, hydrogen atoms in the passivation layer may diffuse into the first conductive contact CT1, and hydrogen atoms in the second interlayer insulating layer IL2 may also diffuse into the first conductive contact CT1. The hydrogen atoms, which are diffused into the first conductive contact CT1, may diffuse into the first semiconductor layer SL1.

The first conductive contact CT1 may be connected to the upper electrode UE and may be spaced apart from the first hydrogen diffusion barrier layer HBP1. For example, the first hydrogen diffusion barrier layer HBP1 may be placed below the first conductive contact CT1 and the first semiconductor layer SL1. For example, a bottom surface CT1_L of the first conductive contact CT1 may be located at a level higher than a top surface of the first hydrogen diffusion barrier layer HBP1. Here, the bottom surface CT1_L of the first conductive contact CT1 may mean a bottom surface of the first barrier pattern BP1. The first hydrogen diffusion barrier layer HBP1 may be placed at a level which is lower than the first conductive contact CT1, and may prevent hydrogen atoms, which are diffused into the first conductive contact CT1, from being diffused into the metal and dielectric layers ML and DE below the first hydrogen diffusion barrier layer HBP1. Thus, it may be possible to prevent the electrical characteristics of the semiconductor device from being deteriorated.

Referring to FIGS. 4 and 5B, the first hydrogen diffusion barrier layer HBP1, the first semiconductor layer SL1, and the first interlayer insulating layer IL1 may be disposed side by side. The first interlayer insulating layer IL1 may be in contact with the upper side surface UE_S of the upper electrode UE, and hydrogen atoms in the first interlayer insulating layer IL1 may diffuse into the first semiconductor layer SL1. The first hydrogen diffusion barrier layer HBP1 may be interposed between the first interlayer insulating layer IL1 and the metal layer ML and prevent the hydrogen atoms in the first interlayer insulating layer IL1 from being diffused into the metal layer ML and the dielectric layer DE.

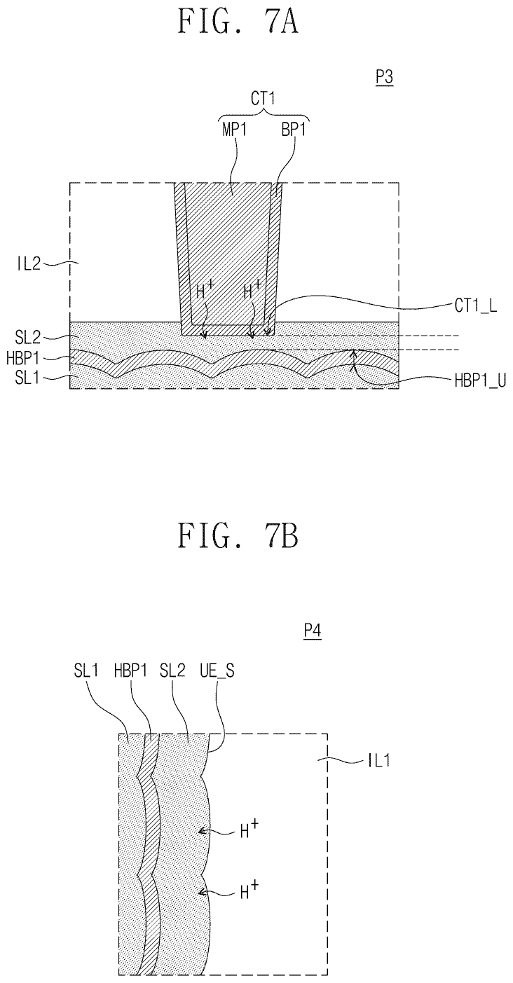

FIG. 6 is a sectional view illustrating the semiconductor device of FIG. 3A, taken along the line C-C′ of FIG. 1. FIG. 7A is an enlarged sectional view illustrating a portion P3 of FIG. 6. FIG. 7B is an enlarged sectional view illustrating a portion P4 of FIG. 6. To the extent that an element has not been described in detail, it may be assumed that the element is at least similar to corresponding elements that have been described in previous figures.

Referring to FIGS. 6 and 7A, the first semiconductor layer SL1, the first hydrogen diffusion barrier layer HBP1, the second semiconductor layer SL2, and the second interlayer insulating layer IL2 may be sequentially disposed. For example, the second interlayer insulating layer IL2 may be disposed on the second semiconductor layer SL2 which is disposed on the first hydrogen diffusion barrier layer HBP1 which is disposed on the first semiconductor layer SL1. The first conductive contact CT1 may be formed on the second semiconductor layer SL2 and penetrate the second interlayer insulating layer IL2 and may be connected to the second semiconductor layer SL2. The first conductive contact CT1 may include the first barrier pattern BP1 and the first metal pattern MP1. The first barrier pattern BP1 may be in contact with the second interlayer insulating layer IL2 and the second semiconductor layer SL2, and the first metal pattern MP1 may be formed in the first barrier pattern BP1.

The first conductive contact CT1 may be connected to the upper electrode UE and be spaced apart from the first hydrogen diffusion barrier layer HBP1. For example, the first hydrogen diffusion barrier layer HBP1 may be placed below the first conductive contact CT1 and the second semiconductor layer SL2. For example, the bottom surface CT1_L of the first conductive contact CT1 may be located at a level higher than the top surface of the first hydrogen diffusion barrier layer HBP1. Accordingly, it may be possible to prevent hydrogen atoms, which are diffused through the first conductive contact CT1, from being diffused into the first semiconductor layer, the metal layer ML, and the dielectric layer DE, which are placed below the first hydrogen diffusion barrier layer HBP1. Thus, it may be possible to prevent the electrical characteristics of the semiconductor device from being deteriorated.

Referring to FIGS. 6 and 7B, the first semiconductor layer SL1, the first hydrogen diffusion barrier layer HBP1, the second semiconductor layer SL2, and the first interlayer insulating layer IL1 may be disposed side by side. The first interlayer insulating layer IL1 may be in contact with the upper side surface UE_S of the upper electrode UE, and hydrogen atoms in the first interlayer insulating layer IL1 may diffuse into the second semiconductor layer SL2. The first hydrogen diffusion barrier layer HBP1 may be interposed between the second semiconductor layer SL2 and the first semiconductor layer SL1 and may prevent hydrogen atoms, which are diffused from the first interlayer insulating layer ILI into the second semiconductor layer SL2, from being diffused into the first semiconductor layer SL1, the metal layer ML, and the dielectric layer DE.

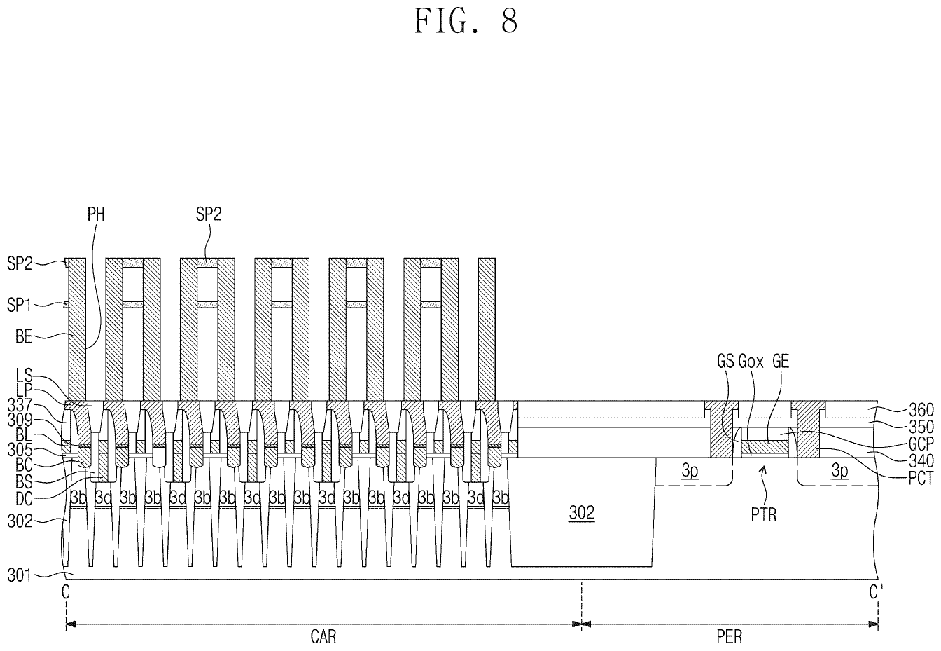

FIGS. 8 to 13 are sectional views sequentially illustrating a process of fabricating the semiconductor device of FIG. 4.

Referring to FIG. 8, the substrate 301 having the cell array region CAR and the peripheral region PER may be provided. The word lines WL, the bit lines BL, the peripheral transistor PTR, the bottom electrodes BE, and the first and second supporting patterns SP1 and SP2 of FIG. 4 may be formed on the substrate 301.

Penetration holes PH may be formed between the bottom electrodes BE, which are adjacent to each other. As an example, each of the penetration holes PH may have a circular shape and may be disposed between three adjacent ones of the bottom electrodes BE and expose a portion of a side surface of each of the three bottom electrodes BE. However, the inventive concept is not limited to this example, and the penetration holes PH may be provided in various shapes, between a plurality of bottom electrodes BE.

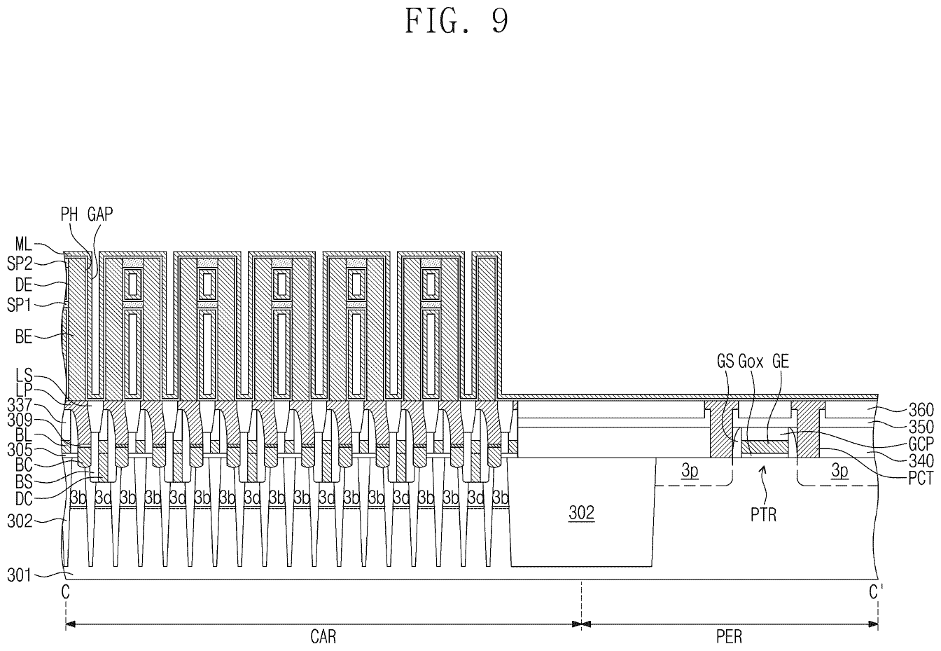

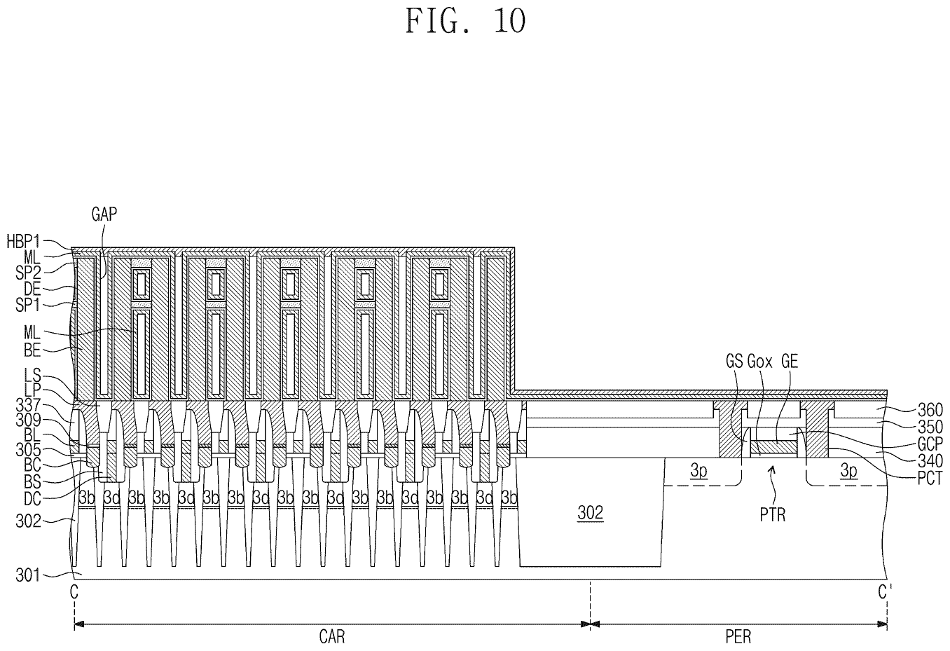

Referring to FIG. 9, the dielectric and metal layers DE and ML may be sequentially formed on the substrate 301. For example, the dielectric layer DE may be disposed closer to the substrate and below the metal layer ML. The formation of the dielectric and metal layers DE and ML may be performed using an atomic layer deposition (ALD) process, a chemical vapor deposition (CVD) process, or a physical vapor deposition (PVD) process. The dielectric and metal layers DE and ML may conformally cover the first supporting pattern SP1, the second supporting pattern SP2, and the bottom electrodes BE. The dielectric and metal layers DE and ML may fill a portion of the penetration hole PH between the bottom electrodes BE, and a remaining portion of the penetration hole PH, which might not be filled with the dielectric and metal layers DE and ML, may form the gap portion GAP. The gap portion GAP may be an empty region, which is not filled with the dielectric and metal layers DE and ML.

Referring to FIG. 10, the first hydrogen diffusion barrier layer HBP1 may be formed on the metal layer ML. The formation of the first hydrogen diffusion barrier layer HBP1 may be performed using an atomic layer deposition (ALD) process, a chemical vapor deposition (CVD) process, or a physical vapor deposition (PVD) process. The first hydrogen diffusion barrier layer HBP1 may fill only a portion of the penetration hole PH. The first hydrogen diffusion barrier layer HBP1 might not fill the entirety of the gap portion GAP between the metal layer ML, and thus, the gap portion GAP may remain in the penetration hole PH, even after the formation of the first hydrogen diffusion barrier layer HBP1. For example, a portion of the bottom surface of the first hydrogen diffusion barrier layer HBP1 might not be in contact with the top surface of the metal layer ML, and thus, the top surface of the metal layer ML may include an exposed portion, which is not covered with the first hydrogen diffusion barrier layer HBP1.

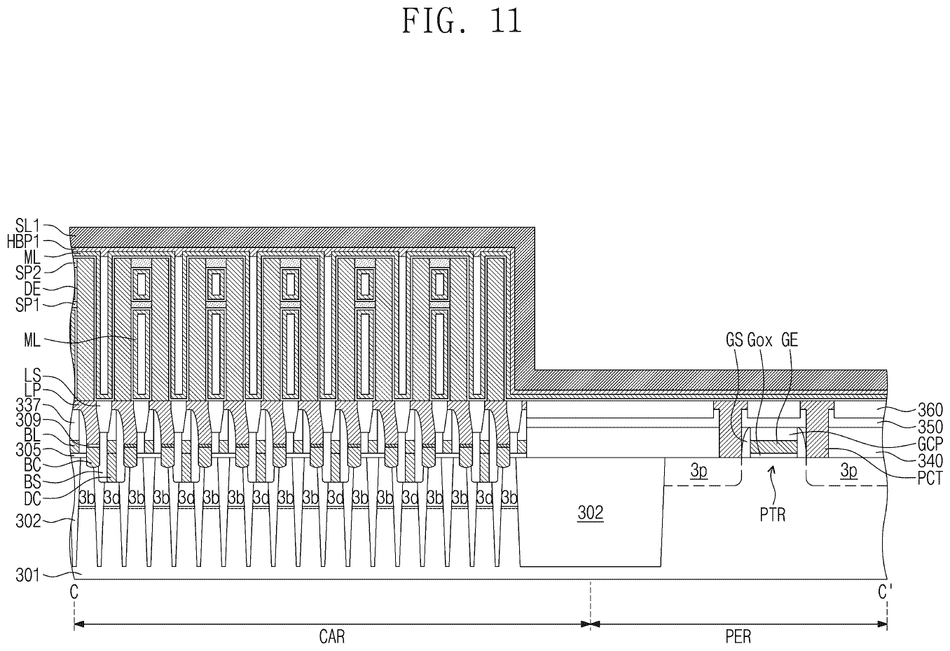

Referring to FIG. 11, the first semiconductor layer SL1 may be formed on the first hydrogen diffusion barrier layer HBP1. The formation of the first semiconductor layer SL1 may be performed using an atomic layer deposition (ALD) process, a chemical vapor deposition (CVD) process, or a physical vapor deposition (PVD) process.

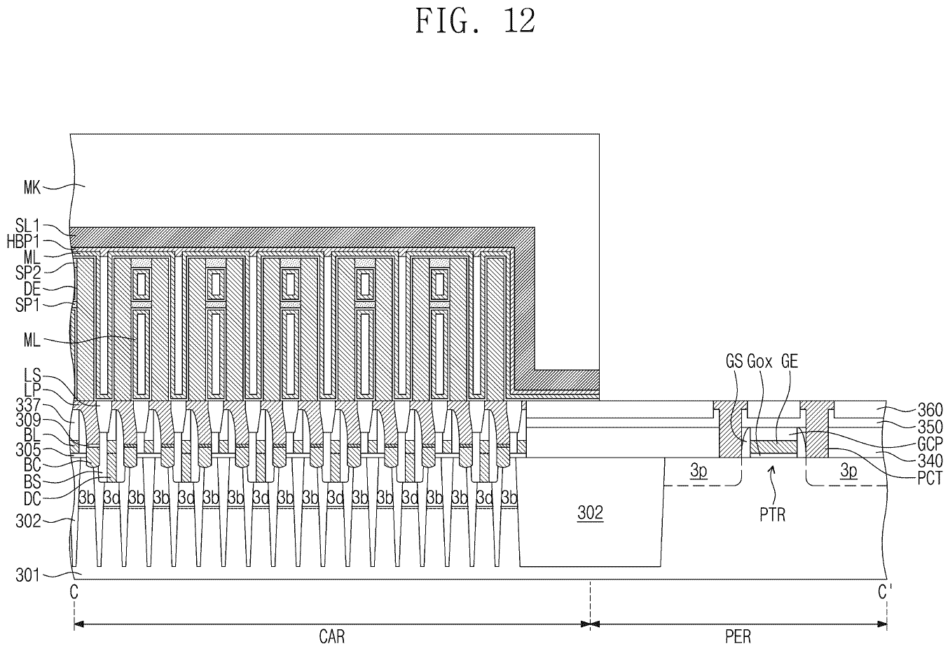

Referring to FIG. 12, a mask pattern MK may be formed on the first semiconductor layer SL1. The mask pattern MK may at least partially cover top and side surfaces of the first semiconductor layer SL1. The mask pattern MK may be a photoresist pattern or a spin-on-hardmask (SOH) pattern. The mask pattern MK may be formed and cover the cell array region CAR and expose the peripheral region PER. The dielectric layer DE, the metal layer ML, and the first semiconductor layer SLI may be removed from the peripheral region PER using the mask pattern MK as an etch mask to form the upper electrode UE and expose the third lower insulating layer 360. Then, the mask pattern MK may be removed by an additional process.

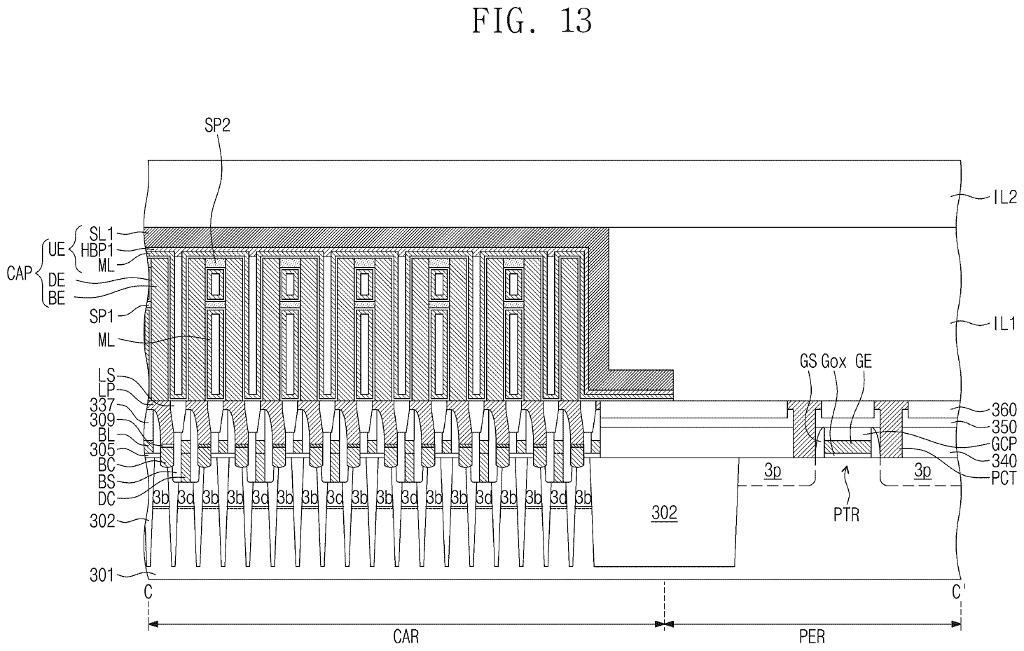

Referring to FIG. 13, the first interlayer insulating layer IL1 may be formed on the substrate 301. The first interlayer insulating layer IL1 may be formed and at least partially cover top and side surfaces of the upper electrode UE, and the peripheral region PER. Then, a polishing process (e.g., a chemical mechanical polishing (CMP) process) may be performed on a top surface of the first interlayer insulating layer IL1. As a result of the polishing process, a top surface of the upper electrode UE may be exposed to the outside and may have a flat or planarized shape. Here, the top surface of the upper electrode UE may have substantially a flat shape, and the side surface of the upper electrode UE may have an uneven shape. The second interlayer insulating layer IL2 may be formed on the first interlayer insulating layer IL1. Then, the first and second conductive contacts CT1 and CT2 and the first peripheral conductive contact PCT1 may be formed.

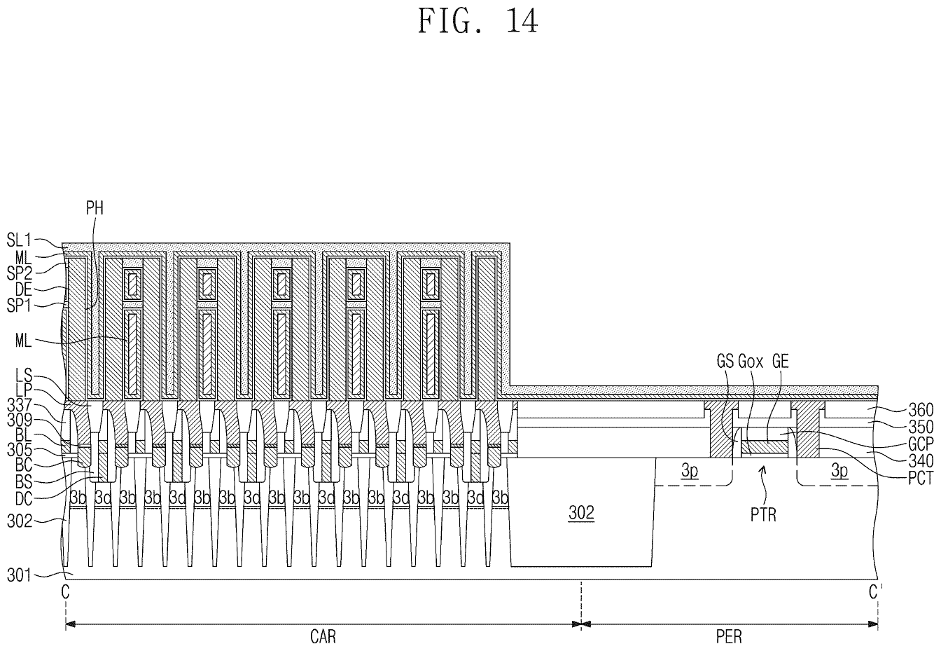

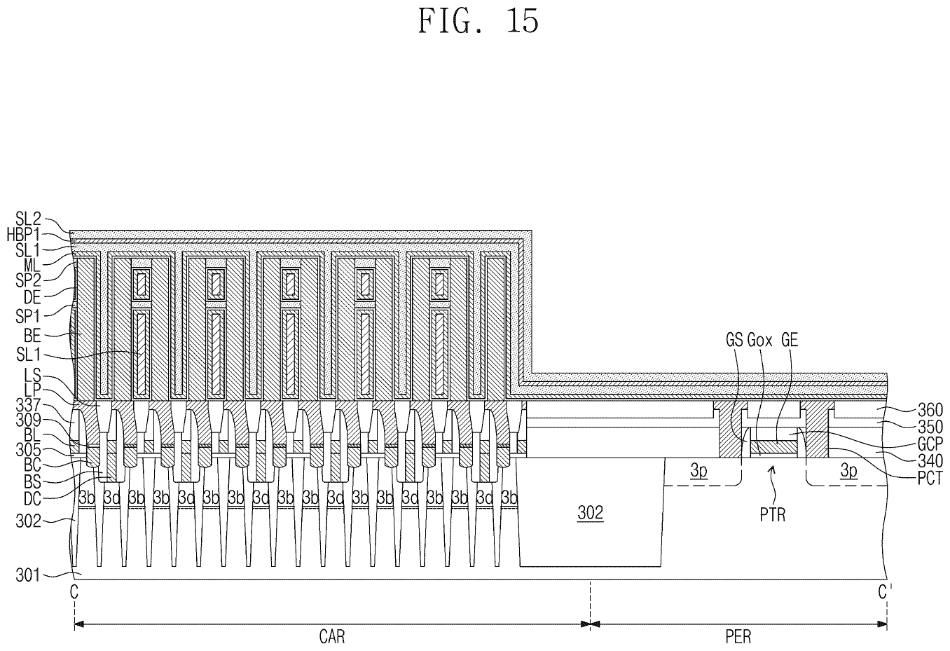

FIGS. 14 and 15 are sectional views sequentially illustrating a process of fabricating the semiconductor device of FIG. 6.

Referring to FIGS. 9 and 14, the first semiconductor layer SL1 may be formed on the metal layer ML. The formation of the first semiconductor layer SL1 may be performed using an atomic layer deposition (ALD) process, a chemical vapor deposition (CVD) process, or a physical vapor deposition (PVD) process. The first semiconductor layer SL1 may fill an unfilled portion of the penetration hole PH. For example, the first semiconductor layer SL1 may fill the entirety of the gap portion GAP between the metal layer ML. In addition, the first semiconductor layer SL1 may fill a remaining empty space between the first and second supporting patterns SP1 and SP2 and a remaining empty space between the first supporting pattern SP1 and the etch stop layer EL.

Referring to FIG. 15, the first hydrogen diffusion barrier layer HBP1 and the second semiconductor layer SL2 may be sequentially formed on the first semiconductor layer SL1. Each of the first hydrogen diffusion barrier layer HBP1 and the second semiconductor layer SL2 may be formed by an atomic layer deposition (ALD) process, a chemical vapor deposition (CVD) process, or a physical vapor deposition (PVD) process. Thereafter, a mask pattern may be formed as previously described with reference to FIGS. 12 to 14, and then, the first semiconductor layer SL1, the first hydrogen diffusion barrier layer HBP1, and the second semiconductor layer SL2 on the peripheral region PER may be removed using the mask pattern to form the upper electrode. Furthermore, first and second interlayer insulating layers may be sequentially formed on the upper electrode.

According to an embodiment of the inventive concept, a hydrogen diffusion barrier layer may be disposed in an upper electrode and prevent hydrogen atoms in an interlayer insulating layer and conductive contacts from being diffused into a bottom electrode and a dielectric layer. Thus, it may be possible to prevent the electrical characteristics of the semiconductor device from being deteriorated.

In addition, although the hydrogen diffusion barrier layer is disposed on the bottom electrode, an overall thickness of the upper electrode may be reduced by decreasing a thickness of a semiconductor layer. This may make it possible to improve the electrical characteristics of the semiconductor device.

While example embodiments of the inventive concept have been particularly shown and described, it will be understood by one of ordinary skill in the art that variations in form and detail may be made therein without departing from the spirit and scope of the attached claims.

What is claimed is:

1. A semiconductor device, comprising:
a substrate;
bottom electrodes disposed on the substrate;
a supporting pattern disposed between the bottom electrodes, when viewed in a plan view;
an upper electrode covering the bottom electrodes and the supporting pattern;
a dielectric layer disposed between the bottom electrodes and the upper electrode and between the supporting pattern and the upper electrode; and
a first conductive contact connected to the upper electrode,
wherein the upper electrode comprises a metal layer, a first hydrogen diffusion barrier layer, and a first semiconductor layer, which are sequentially stacked on the dielectric layer, and
wherein the first conductive contact is spaced apart from the first hydrogen diffusion barrier layer.

2. The semiconductor device of claim 1, wherein the first hydrogen diffusion barrier layer comprises at least one of titanium, tungsten, titanium nitride, tungsten nitride, titanium silicon nitride, or tungsten silicon nitride.

3. The semiconductor device of claim 1, wherein the first semiconductor layer comprises silicon germanium (SiGe).

4. The semiconductor device of claim 1, wherein the upper electrode further comprises a second hydrogen diffusion barrier layer disposed on the first semiconductor layer and a second semiconductor layer disposed on the second hydrogen diffusion barrier layer.

5. The semiconductor device of claim 4, wherein each of the first and second semiconductor layers comprises silicon germanium.

6. The semiconductor device of claim 1, wherein the upper electrode further comprises a plurality of hydrogen diffusion barrier layers and a plurality of semiconductor layers, which are alternatively stacked on the first semiconductor layer, and
wherein the first conductive contact is connected to an uppermost one of the semiconductor layers.

7. The semiconductor device of claim 6, wherein each of the semiconductor layers comprises silicon germanium (SiGe).

8. The semiconductor device of claim 1, wherein a thickness of the first hydrogen diffusion barrier layer is smaller than a thickness of the first semiconductor layer.

9. The semiconductor device of claim 1, wherein a bottom surface of the first conductive contact is disposed at a level higher than a top surface of the first hydrogen diffusion barrier layer.

10. The semiconductor device of claim 1, further comprising:
a first interlayer insulating layer covering a side surface of the upper electrode; and
a second interlayer insulating layer disposed on a top surface of the upper electrode and a top surface of the first interlayer insulating layer,
wherein the first conductive contact penetrates the second interlayer insulating layer and is in contact with the first semiconductor layer.

11. The semiconductor device of claim 1, wherein the first and second interlayer insulating layers include a hydrogen-containing insulating material.

12. A semiconductor device, comprising:
a substrate;
bottom electrodes on the substrate;
a supporting pattern disposed between the bottom electrodes, when viewed in a plan view;
an upper electrode covering the bottom electrodes and the supporting pattern; and
a dielectric layer provided between the bottom electrodes and the upper electrode and between the supporting pattern and the upper electrode,
wherein the upper electrode comprises a metal layer, a first semiconductor layer, a first hydrogen diffusion barrier layer, and a second semiconductor layer, which are sequentially stacked on the dielectric layer, and
wherein each of the first and second semiconductor layers comprises silicon germanium.

13. The semiconductor device of claim 12, wherein the first hydrogen diffusion barrier layer comprises at least one of titanium, tungsten, titanium nitride, tungsten nitride, titanium silicon nitride, or tungsten silicon nitride.

14. The semiconductor device of claim 12, wherein the upper electrode further comprises a second hydrogen diffusion barrier layer disposed on the second semiconductor layer and a third semiconductor layer disposed on the second hydrogen diffusion barrier layer, and
wherein the third semiconductor layer comprises silicon germanium (SiGe).

15. The semiconductor device of claim 12, wherein the upper electrode further comprises a plurality of hydrogen diffusion barrier layers and a plurality of semiconductor layers, which are alternatively stacked on the second semiconductor layer,
wherein an uppermost one of the semiconductor layers is located at a level higher than the uppermost one of the hydrogen diffusion barrier layers, and
wherein each of the semiconductor layers comprises silicon germanium (SiGe).

16. The semiconductor device of claim 12, further comprising:
a first interlayer insulating layer covering a side surface of the upper electrode;
a second interlayer insulating layer disposed on the upper electrode and the first interlayer insulating layer; and
a first conductive contact penetrating the second interlayer insulating layer and connected to the second semiconductor layer,
wherein a bottom surface of the first conductive contact is disposed at a level higher than a top surface of the first hydrogen diffusion barrier layer.

17. The semiconductor device of claim 16, wherein each of the first and second interlayer insulating layers includes a hydrogen-containing insulating material.

18. A semiconductor device, comprising:
a substrate including a cell array region and a peripheral region;
a word line disposed on the cell array region of the substrate;
a first impurity region disposed in a portion of the substrate at a side of the word line;
a second impurity region disposed in a portion of the substrate at an opposite side of the word line;
a bit line disposed on the cell array region of the substrate crossing the word line and connected to the first impurity region;
bottom electrodes disposed on the cell array region of the substrate and connected to the second impurity region;
a supporting pattern disposed between the bottom electrodes, when viewed in a plan view;
an upper electrode covering the bottom electrodes and the supporting pattern;
a dielectric layer disposed between the bottom electrodes and the upper electrode and between the supporting pattern and the upper electrode; and
a first conductive contact coupled to the upper electrode,
wherein the upper electrode comprises a metal layer, a first hydrogen diffusion barrier layer, and a first semiconductor layer, which are sequentially stacked on the dielectric layer, and
wherein the first conductive contact is spaced apart from the first hydrogen diffusion barrier layer and is in contact with the first semiconductor layer.

19. The semiconductor device of claim 18, wherein the first hydrogen diffusion barrier layer comprises at least one of titanium, tungsten, titanium nitride, tungsten nitride, titanium silicon nitride, or tungsten silicon nitride.

20. The semiconductor device of claim 18, further comprising:
a first interlayer insulating layer covering a side surface of the upper electrode; and
a second interlayer insulating layer on the upper electrode and the first interlayer insulating layer,
wherein a bottom surface of the first conductive contact is located at a level higher than a top surface of the first hydrogen diffusion barrier layer.
